(19) United States
(12) Patent Application Publication
(10) Pub. No.: US 2010/0147371 A1
(43) Pub. Date: Jun. 17, 2010

(54) Energy harvesting devices

(75) Inventor: Sung Nae Cho, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/654,254

(22) Filed: Dec. 15, 2009

(30) Foreign Application Priority Data
Dec. 15, 2008 (KR) 10-2008-0127271
Jul. 9, 2009 (KR) 10-2009-062569

(51) Int. Cl. H01L 27/142

(52) U.S. Cl. 136/255; 257/443; 977/932; 257/461; 257/E27.123

(57) ABSTRACT

Energy harvesting devices including first nano-helixes amplifying incident electromagnetic waves, second nano-helixes inducing currents from the electromagnetic waves amplified by the first nano-helixes, and a diode rectifying induced currents generated by the second nano-helixes.

### CROSS-REFERENCE TO RELATED APPLICATIONS

This application claims the benefit of priority under 35 U.S.C. §119 from Korean Patent Application No. 10-2008-0127271, filed on Dec. 15, 2008, and Korean Patent Application No. 10-2009-0062569, filed on Jul. 9, 2009, in the Korean Intellectual Property Office, the disclosures of which are incorporated herein in their entirety by reference.

### BACKGROUND

1. Field

Example embodiments relate to energy harvesting devices, and more particularly, to energy harvesting devices having a nano-helix.

2. Description of the Related Art

Early energy harvesting devices have been introduced in order to address power supply problems in, for example, remote devices or embedded devices. Such energy harvesting devices harvest energy by themselves for a semi-permanent power supply in environments where it is difficult for users to frequently replace batteries or recharge batteries using another device.

According to energy harvesting (a.k.a. energy scavenging) techniques, energy (e.g., kinetic energy, light energy, electromagnetic wave energy and thermal energy) in a surrounding environment is converted into electric energy through piezoelectrification, photo power generation, thermoelectric power generation and/or electromagnetic induction. For example, energy harvesting devices using solar light are attached to road (or outdoor) surveillance cameras or street lights. Energy harvesting devices are used in many applications due to the developments in power management integrated circuits (IC), power storage techniques and low-power ICs, and the improvements in energy conversion efficiency.

Energy harvesting devices are environment-friendly and have energy saving purposes. Energy harvesting devices may offer more sufficient reserve power for various devices.

### SUMMARY

Example embodiments relate to energy harvesting devices, and more particularly, to energy harvesting devices using nano-helixes.

Additional aspects will be set forth in part in the description which follows and, in part, will be apparent from the description, or may be learned by practice of example embodiments.

According to example embodiments, an energy harvesting device includes first nano-helixes amplifying incident electromagnetic waves, second nano-helixes inducing currents from the electromagnetic waves amplified by the first nano-helixes, and a diode rectifying the induced currents generated by the second nano-helixes.

Here, the incident electromagnetic waves may be generated by a natural light source (e.g., the sun) or an artificial light source (e.g., an indoor/outdoor lamp, a wireless station or a wireless device).

The first and second nano-helixes may be formed of a conductive material, for example. The first and second nano-helixes may be arranged close to each other. A plurality of the first nano-helixes may be arranged on a first substrate, and a plurality of second nano-helixes may be arranged on a second substrate. The first substrate and the second substrate may be stacked.

A plurality of the first substrates may be stacked. The first nano-helixes and the second nano-helixes may be either horizontally or vertically grown on the first substrate and the second substrate, respectively.

An equalizing circuit may be connected to the diode to equalize rectified currents. A storage battery may be connected to the equalizing circuit to store equalized currents.

According to example embodiments, an energy harvesting device includes a primary nano-helix layer having a plurality of first nano-helixes for amplifying incident electromagnetic waves, a secondary nano-helix layer having a plurality of second nano-helixes for inducing currents from the electromagnetic waves amplified by the primary nano-helix layer, and a diode unit layer having a plurality of diodes for rectifying the currents induced by the secondary nano-helix layer.

The primary nano-helix layer includes a first insulation layer, a ground electrode disposed on the first insulation layer, and a plurality of first nano-helixes disposed on the first insulation layer and the ground electrode. The first nano-helixes may be electrically connected to the ground electrode at a point.

The plurality of first nano-helixes may be randomly distributed on the first insulation layer. The plurality of first nano-helixes may be covered and fixed by a coating layer disposed thereon.

For example, a thickness of the first insulation layer may be from about 1 nm to about 100 μm.

The ground electrode may include a plurality of conductive wires formed on the first insulation layer in a side-by-side configuration. A second insulation layer may be interposed between the ground electrode and the first nano-helix.

The primary nano-helix layer may be formed by sequentially forming the first nano-helixes, the second insulation layer, the ground electrode and the first insulation layer on a substrate.

At least the two primary nano-helix layers having the same structure may be successively stacked in a travelling direction of the incident electromagnetic waves.

The secondary nano-helix layer may include a third insulation layer, and a plurality of second nano-helixes arranged on the third insulation layer.

The diode unit layer may include a plurality of diode cells. Each of the diode cells may include a pair of wires, which penetrate the third insulation layer and are electrically connected to both ends of the second nano-helix. The diode unit layer may also include a diode for rectifying induced currents flowing in the pair of wires. Condensers for equalizing rectified currents may be connected to each of the diode cells.

The diode cells may be connected to each other in series, in parallel, or in a combination of a serial connection and a parallel connection.

A fourth insulation layer may be interposed between the third insulation layer and the second nano-helixes.

The plurality of second nano-helixes may be covered and fixed by a coating layer disposed thereon.

According to example embodiments, an energy harvesting device includes a nano-helix layer having a plurality of nano-helixes that are arranged vertically, an electrode connected to first ends of the nano-helixes, and a diode layer connected to second ends of the nano-helixes.

The nano-helix layer may include an insulation layer, and a plurality of nano-helixes vertically arranged in the insulation layer, and the both ends of the plurality of nano-helixes are exposed to outside from the upper and lower surfaces of the insulation layer.

The diode layer may include a first semiconductor layer disposed on the upper surface of the nano-helix layer, and a second semiconductor layer disposed on the first semiconductor layer. The first and second semiconductor layers may be doped to opposite types.

The plurality of nano-helixes may be electrically connected to the first semiconductor layer.

A condenser layer may be disposed on the upper surface of the diode layer.

The condenser layer may include a first conductor layer disposed on the second semiconductor layer, a dielectric layer disposed on the first conductor layer, and a second conductor layer disposed on the dielectric layer.

The electrode and the second conductor layer may be connected to a ground, and the second semiconductor layer may be connected to an output.

The diode layer may be divided into a plurality of diode cells.

At least one of the diode cells of the diode layer may be connected to one of the nano-helixes of the nano-helix layer.

A resistance layer may be interposed between the nano-helix layer and the electrode.

According to example embodiments, an energy harvesting device includes a nano-helix layer, which includes a substrate, an electrode layer formed on the substrate, and a plurality of nano-helixes vertically grown on the electrode layer. The energy harvesting device includes a diode layer disposed on the nano-helix layer and electrically connected to the plurality of nano-helixes.

A plurality of dielectric spacers may be interposed between the electrode layer of the nano-helix layer and the diode layer. The dielectric spacers may support the diode layer.

An insulation layer may be interposed between the electrode layer of the nano-helix layer and the diode layer.

A resistance layer may be interposed between the electrode layer and the nano-helixes.

A condenser layer may be disposed on an upper surface of the diode layer.

### BRIEF DESCRIPTION OF THE DRAWINGS

These and/or other aspects will become apparent and more readily appreciated from the following description of the example embodiments, taken in conjunction with the accompanying drawings of which:

FIG. 1 is a schematic diagram of an energy harvesting device according to example embodiments;

FIG. 2 is a diagram showing a ground electrode of the energy harvesting device shown in FIG. 1;

FIG. 3 is a diagram of an equivalent circuit of the energy harvesting device shown in FIG. 1;

FIG. 4 is a diagram for describing the mechanism of electromagnetic wave amplification by using a nano-helix;

FIG. 5 is a graph showing changes of intensity of magnetic waves amplified by a nano-helix according to an azimuth direction;

FIG. 6 is a graph showing changes of intensity of electric waves amplified by a nano-helix according to an azimuth direction;

FIG. 7 is a schematic diagram of an energy harvesting device according to example embodiments;

FIG. 8 is a schematic diagram showing the structure of a primary nano-helix layer according to example embodiments;

FIG. 9 is a schematic diagram showing the structure of a primary nano-helix layer according to example embodiments;

FIG. 10 is a schematic diagram showing the structure of a primary nano-helix layer according to example embodiments;

FIG. 11 is a schematic diagram showing the structure of a secondary nano-helix layer according to example embodiments;

FIG. 12 is a diagram of an equivalent circuit of the energy harvesting device according to example embodiments;

FIGS. 13, 14A and 14B are schematic diagrams showing the structure of nano-helix layers according to example embodiments;

FIG. 15 is a schematic diagram of an energy harvesting device including the nano-helix layer shown in FIG. 14B;

FIGS. 16 and 17 are schematic diagrams of energy harvesting devices including the nano-helix layer shown in FIG. 14B;

FIG. 18 shows an equivalent circuit of the energy harvesting device shown in FIG. 17;

FIGS. 19 and 20 are schematic diagrams of energy harvesting devices including the nano-helix layer shown in FIG. 14B;

FIG. 21 is a schematic diagram of the energy harvesting devices shown in FIG. 20; and

FIGS. 22 and 23 are schematic diagrams showing the structure of nano-helix layers according to example embodiments.

### DETAILED DESCRIPTION

Various example embodiments will now be described more fully with reference to the accompanying drawings in which some example embodiments are shown. However, specific structural and functional details disclosed herein are merely representative for purposes of describing example embodiments. Thus, the invention may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the invention.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In order to more specifically describe example embodiments, various aspects will be described in detail with reference to the attached drawings. However, the present invention is not limited to example embodiments described.

Example embodiments relate to energy harvesting devices, and more particularly, to energy harvesting devices having a nano-helix.

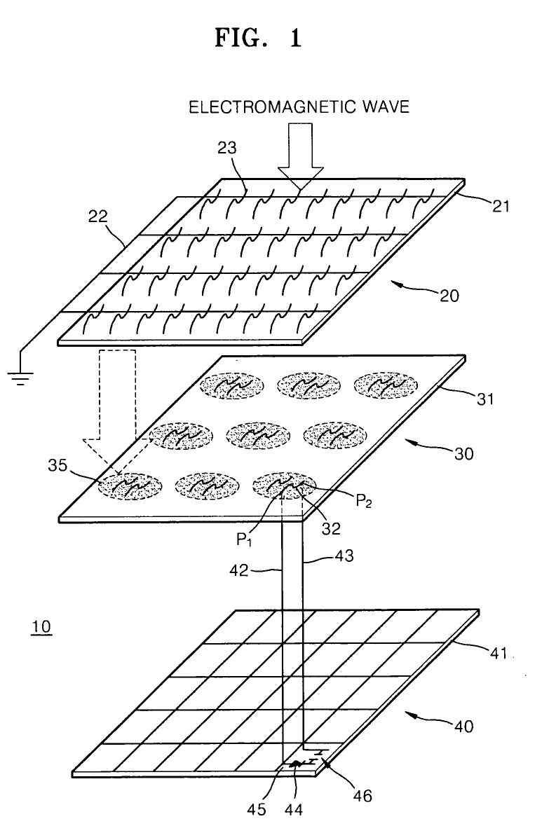

FIG. 1 is a schematic diagram of an energy harvesting device according to example embodiments.

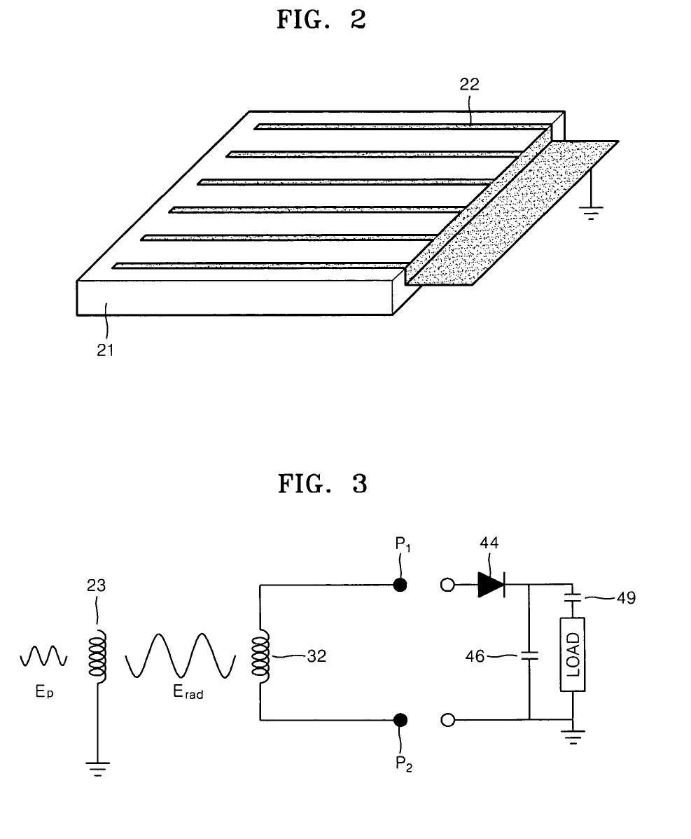

FIG. 2 is a diagram showing a ground electrode of the energy harvesting device shown in FIG. 1.

Referring to FIG. 1, the energy harvesting device 10 includes a primary nano-helix layer 20 for amplifying incident electromagnetic waves, a secondary nano-helix layer 30 for generating induced currents from the amplified electromagnetic waves via an electromagnetic induction phenomenon, and a diode unit layer 40 for rectifying the induced currents, for example, generated by the secondary nano-helix layer into direct currents. The primary nano-helix layer 20, the secondary nano-helix layer 30 and the diode unit layer 40 may be sequentially arranged along a direction in which the incident electromagnetic waves travel.

The term ‘incident electromagnetic waves’ are understood as including all kinds of electromagnetic waves and radiations. For example, the energy source of incident electromagnetic wave may be the sun radiating sunlight containing infrared ray, visible rays and ultraviolet rays. Indoor/outdoor electric lamps may be used for generating incident electromagnetic waves, for example. A nearby wireless station or wireless devices, which generates high frequency signals, may be used in this regard.

The primary nano-helix layer 20 includes a thin-film insulation layer 21, ground electrodes 22 disposed on the thin-film insulation layer 21, and a plurality of first nano-helixes 23 that are arranged in arrays on the thin-film insulation layer 21 and electrically connected to the ground electrodes 22. The ground electrode 22 may include a plurality of conductive wires that are arranged side by side on the thin-film insulation layer 21 as shown in FIG. 2. The conductive wires may be connected to a single metal plate on a lateral surface of the thin-film insulation layer 21. As shown in FIG. 1, each of the plurality of first nano-helixes 23 may electrically contact a corresponding ground electrode 22.

The thin-film insulation layer 21 may be formed of a material that transmits incident electromagnetic waves. For example, when the incident electromagnetic waves are visible rays, the thin-film insulation layer 21 may be formed of a material that is transparent with respect to visible rays. Hereinafter, the term ‘transparent’ indicates transmittance with respect to incident electromagnetic waves. As described below, the thickness of the thin-film insulation layer 21 may be from about 1-nm to about 100-nm for amplification of incident electromagnetic wave via the first nano-helixes 23.

The secondary nano-helix layer 30 includes an insulation layer 31 and a plurality of second nano-helixes 32 that are arranged in arrays on the insulation layer 31. The insulation layer 31 may be formed of the same material as the thin-film insulation layer 21 of the primary nano-helix layer 20, for example. The insulation layer 31 may be formed of a material that is transparent with respect to incident electromagnetic waves. For example, when the incident electromagnetic waves are visible rays, the insulation layer 31 may be formed of a material that is transparent with respect to visible rays. The insulation layer 31 of the secondary nano-helix layer 30 may have a thickness sufficient for providing sufficient electrical insulation between the second nano-helixes 32 on the upper surface of the insulation layer 31 and the diode unit layer 40 below the insulation layer 31.

The plurality of second nano-helixes 32 may be identical to the plurality of first nano-helixes 23 of the primary nano-helix layer 20. As described below, electromagnetic waves, which are amplified by the first nano-helixes 23 of the primary nano-helix layer 20, are incident onto the insulation layer 31 in a set regional pattern 35. The second nano-helixes 32 of the secondary nano-helix layer 30 may be distributed in the set regional pattern 35 of the incident electromagnetic waves. The second nano-helixes 32 generate induced currents from the amplified incident electromagnetic waves via the electromagnetic induction principle.

The first and second nano-helixes 32 and 32 are formed by spirally winding nanowires formed of conductive materials. Each of the first and second nano-helixes 23 and 32 has a length of about several μm, a helical diameter of about dozens of nm, and a pitch between the helical curves is about dozens of nm. The first and second nano-helixes 23 and 32 may be referred to as nano-scale conductive coils. For example, a nano-helix formed of silicon carbide (SiC) has been suggested. The first and second nano-helixes 23 and 32 may be formed of a conductive material (e.g., a carbon nanotube (CNT) or a metal), instead of SiC.

The diode unit layer 40 includes a plurality of pairs of wires 42 and 43, which penetrate the insulation layer 31 and are electrically connected to the second nano-helixes 32. The diode unit layer 40 includes a plurality of diodes 44, which are formed on a substrate 41 to rectify induced currents flowing in the wires 42 and 43 into direct currents. The diodes 44 may be arranged to form a half-wave rectifier or a full-wave rectifier, for example. As shown in FIG. 1, the wires 42 and 43 are each electrically connected to a respective end P₁ and P₂ of one of the second nano-helixes 32. For convenience of explanation, FIG. 1 shows a diode cell 45 including only one pair of the wires 42 and 43 and one diode 44. However, a plurality of pairs of wires may be respectively connected to the second nano-helixes 32, and a plurality of diodes may be connected to the wires to form one diode cell 45. A direct current may be provided by connecting the plurality of diode cells 45 in series, in parallel or a combination of a serial connection and a parallel connection depending on the demand.

Each of the diode cells 45 may include a condenser 46 for current equalization. Although FIG. 1 only shows the condenser 46, a more complex equalizing circuit may be formed.

FIG. 3 is a diagram of an equivalent circuit of the energy harvesting device shown in FIG. 1.

As shown in FIG. 3, the first nano-helix 23 of the primary nano-helix layer 20 may correspond to a primary coil of a transformer, whereas the second nano-helix 32 of the secondary nano-helix layer 30 may correspond to a secondary coil of the transformer. An incident electromagnetic wave Eₚ is radiated by the first nano-helix 23, and incident electromagnetic wave E_{rad} is incident onto the second nano-helix 32. An induced current generated by the second nano-helix 32 may be rectified by the diode 44 and then may be provided to a load. FIG. 3 shows that a storage battery 49 is disposed between the diode 44 and the load. The storage battery 49 stores currents equalized by the condenser 46 or an equalizing circuit. Equalized currents are finally stored in the storage battery 49, so that the equalized currents may be provided to the load when necessary.

Hereinafter, operations of the energy harvesting device will now be described.

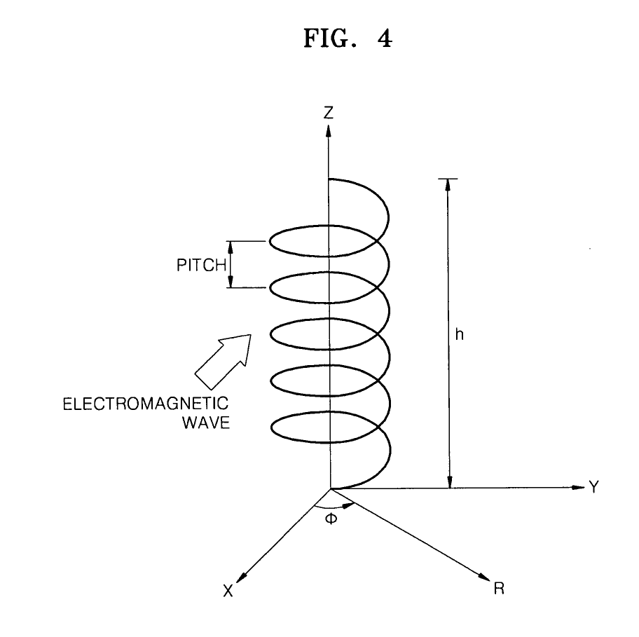

FIG. 4 is a diagram for describing the mechanism of electromagnetic wave amplification by using a nano-helix.

Generally, an electromotive force induced from electromagnetic waves to conductive coils is relatively small. Therefore, it is necessary to amplify externally incident electromagnetic waves. The first nano-helix 23 of the primary nano-helix layer 20 may amplify such incident electromagnetic waves.

As shown in FIG. 4, it is assumed that a plane wave having a substantially uniform wavelength is incident onto a nano-helix at a certain angle. In a macroscopic system, external lights and electromagnetic waves may not be considered as plane waves in general. In the case of a nano-helix, a pitch between helical curves is only about dozens of nm, whereas the wavelength of incident electromagnetic waves having a relatively short wavelength is at least hundreds of nm. An electromagnetic wave incident between helical curves of a nano-helix may be considered a plane wave having a uniform wavelength. A nano-helix functions as multi-slits, and thus patterns interfering with each other due to wave diffraction are formed in the vicinity of the nano-helix. The electromagnetic wave may be significantly (or substantially) amplified at a location close to the nano-helix in a similar manner with amplification due to a near-field effect.

For example, if an incident electromagnetic wave is a green visible ray with a the frequency of 555 nm, the helical diameter of a nano-helix is 40 nm, a pitch between helical curves of the nano-helix is 50 nm, the electric conductivity of the nano-helix is 5×10⁵ S, the length of the nano-helix when straightened is 5 μm, and the number of turns of the nano-helix is 19.5, then the intensity of an electromagnetic wave at a location 273 nm apart from the center axis of the nano-helix may be calculated. As shown in FIG. 4, a cylindrical coordinate system in which the center axis of a nano-helix is the z-axis may be used, wherein the coordinate R is fixed at 273 nm, and changes in intensities of electromagnetic wave amplified by the nano-helix may be calculated based on the azimuth direction CD and coordinate h along the z axis.

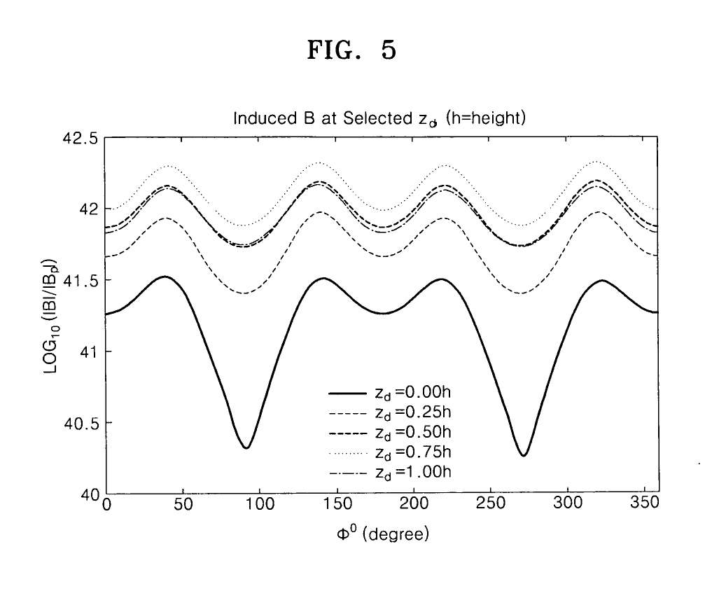

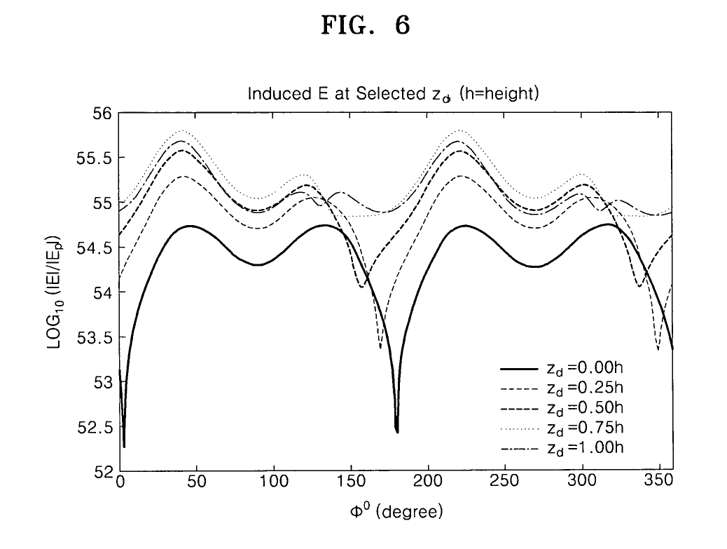

FIGS. 5 and 6 are graphs showing results of calculating changes in intensities of an electromagnetic wave amplified by the nano-helix with respect to magnetic components and electric components, respectively.

In the graphs shown in FIGS. 5 and 6, h is the height of the nano-helix. Furthermore, |B| and |E| respectively are absolute values of magnetic field and electric field induced by the nano-helix, and |Bₚ| and |Eₚ| respectively are absolute values of intensities of incident magnetic field and incident electric field, respectively. Referring to FIGS. 5 and 6, the intensities of electric field and magnetic field induced by the nano-helix are distributed in periodical patterns in an azimuth direction, and the intensities are at the peaks at ¾ of the height of the nano-helix (=0.75 h). Considering that the unit of the vertical axis of the graphs is in log values, it is obvious that significantly amplified electromagnetic waves may be obtained at a location close to the nano-helix (e.g., 273 nm). The amplification effect is reduced at locations farther from the nano-helix.

Electromagnetic waves significantly (or substantially) amplified by the first nano-helix 23 may be incident onto the second nano-helix 32 if the second nano-helix 32 is arranged close to the first nano-helix 23. As such, a sufficiently high electromotive force may be induced by the second nano-helix 32. The thin-film insulation layer 21 may have a thickness from about 100 nm to about 1 μm.

Referring to FIG. 1, the regional pattern 35 may appear on the insulation layer 31 as the amplification effects due to the first nano-helixes 23 overlap. Because intensities of the electromagnetic waves are amplified within the regional pattern 35, a sufficiently high electromotive force may be induced by the second nano-helixes 32 within the regional pattern 35. The induced currents may be transmitted to the diode cell 45 below the insulation layer 31 via the wires 42 and 43 and may be rectified to direct currents, as described above.

FIG. 1 shows that the first and second nano-helixes 23 and 32 are arranged side by side in the same direction in arrays. However, the cost to arrange nano-scale nano-helixes in such manner may be high.

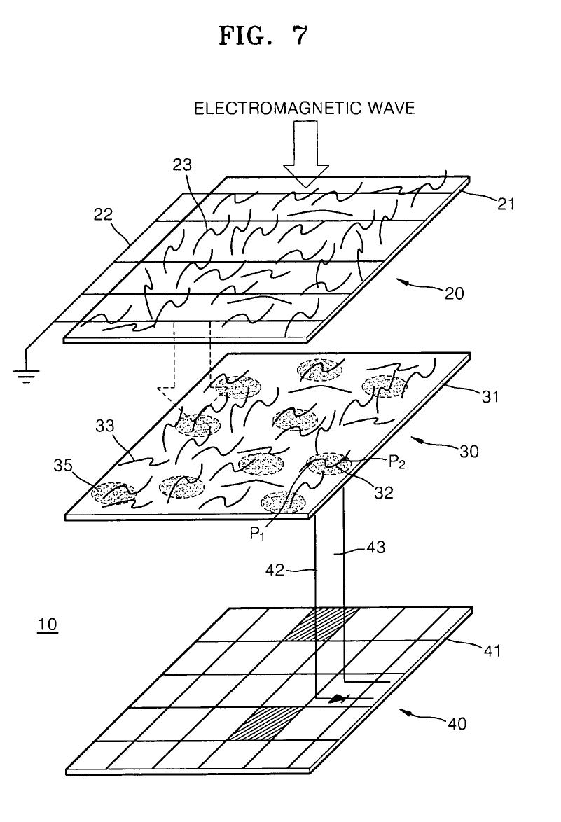

FIG. 7 is a schematic diagram of an energy harvesting device according to example embodiments.

FIG. 7 shows example embodiments of arranging the first and second nano-helixes 23 and 32.

As shown in FIG. 7, the first and second nano-helixes 23 and 32 may be randomly distributed on the insulation layers 21 and 31, respectively. A part of the first nano-helixes 23 may not electrically contact the ground electrodes 22. Because a large number of the first nano-helixes 23 are distributed on the thin-film insulation layer 21, a sufficient number of the first nano-helixes 23 may electrically contact the ground electrodes 22. In the same manner, a part (or some) of the second nano-helixes 32 may not be electrically connected to the wires 42 and 43. Because a large number of the second nano-helixes 32 are distributed on the insulation layer 31, a sufficient number of the second nano-helixes 32 may be electrically interconnected between pairs of the wires 42 and 43. Although the energy harvesting device shown in FIG. 7 has lower efficiency than the energy harvesting device shown in FIG. 1, the energy harvesting device shown in FIG. 7 may be fabricated using a more simple fabrication process and lower costs compared to the energy harvesting device shown in FIG. 1. Although not shown, the first and second nano-helixes 23 and 32 may be covered and fixed by a coating layer formed of a suitable electromagnetic wave transmissive material.

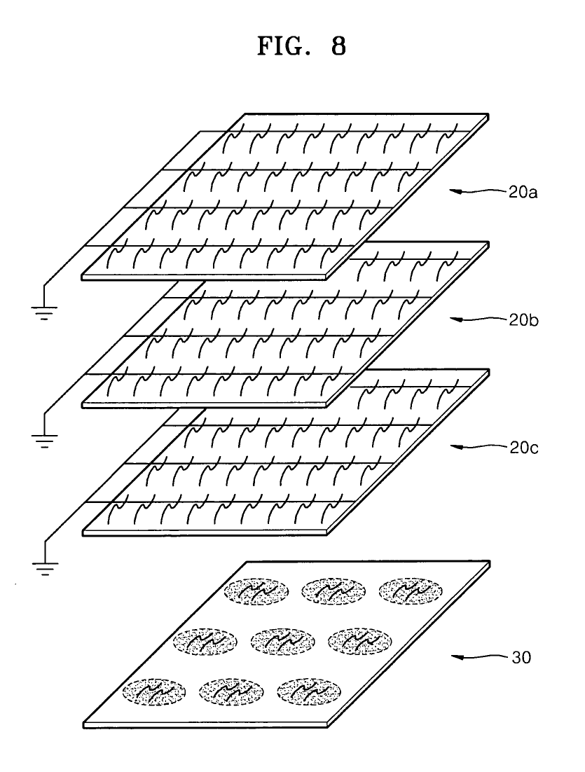

FIG. 8 is a schematic diagram showing the structure of a primary nano-helix layer according to example embodiments.

If, for example, the intensity of external light or electromagnetic wave is small like in an outdoor environment at night, a sufficient amplification effect may not be obtained with one primary nano-helix layer. Therefore, as shown in FIG. 8, at least two primary nano-helix layers 20a through 20c, which have the same shape, may be disposed to provide light of a sufficient intensity to the secondary nano-helix layer 30 by amplifying the light several times. Although FIG. 8 shows three primary nano-helix layers 20a through 20c, example embodiments are not limited thereto. For example, either only two nano-helix layers, or four or more nano-helix layers may be used. Each of the primary nano-helix layers 20a through 20c may have the same structure as the primary nano-helix layer 20 shown in FIGS. 1 and 7. Thus, an electromagnetic wave of a sufficient intensity, which is amplified several times, may be incident onto the secondary nano-helix layer 30.

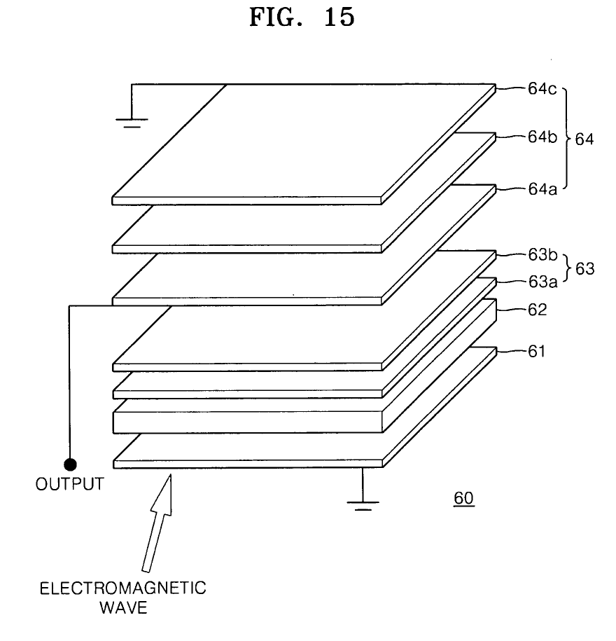

Although not shown in FIGS. 1 and 7, the energy harvesting device 10 may be formed without the primary nano-helix layer 20 if sufficient energy may be obtained by using the secondary nano-helix layer 30 only. Detailed descriptions thereof will be given below in reference to example embodiments shown in FIG. 15.

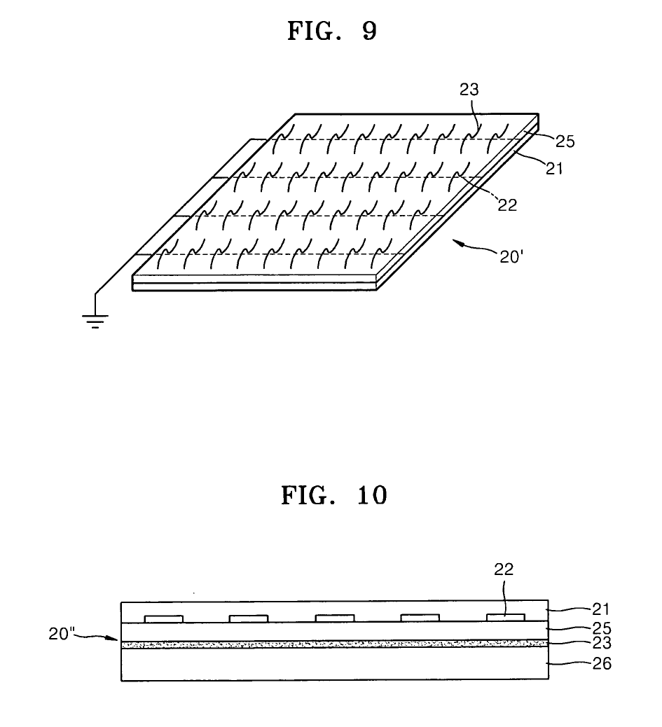

FIG. 9 is a schematic diagram showing the structure of a primary nano-helix layer according to example embodiments.

Because diameters of nanowires forming the nano-helixes are very small, the nanowires may be cut due to overload if large currents are applied thereto. For example, a nanowire formed of ZnO₂ is cut if a current over 300 nA at 30V flows through the nanowire. A resistance layer may be interposed between the first nano-helix 23 and the ground electrode 22 to prevent (or reduce) the application of a large current or large voltage to the first nano-helix 23. For example, in the case of the primary nano-helix layer 20′ according to example embodiments shown in FIG. 9, an additional insulation layer 25 may be disposed on the ground electrode 22 such that the ground electrodes 22 and the first nano-helixes 23 do not directly contact each other, and then the first nano-helixes 23 may be distributed on the additional insulation layer 25. In other words, the primary nano-helix layer 20′ according to example embodiments shown in FIG. 9 includes the ground electrodes 22 formed on the thin-film insulation layer 21, the additional insulation layer 25 formed on the ground electrodes 22, and the first nano-helixes 23 distributed on the additional insulation layer 25. As such, most of the voltage is drop in the additional insulation layer 25, and thus the first nano-helixes 23 may be protected. The additional insulation layer 25 may also be formed of the same electromagnetic wave transmissive material as the thin-film insulation layer 21.

FIG. 10 is a schematic diagram showing the structure of a primary nano-helix layer according to example embodiments.

As described above, because the thickness of the thin-film insulation layer 21 is substantially small, it may be difficult to sequentially form the ground electrodes 22, the additional insulation layer 25 and the first nano-helixes 23 on the thin-film insulation layer 21 because the thin-film insulation layer 21 may be damaged during the fabrication process. A primary nano-helix layer 20″ may be formed. For example, in FIG. 10, the first nano-helixes 23 are distributed on a relatively thick substrate 26, and then the additional insulation layer 25, the ground electrodes 22 and the thin-film insulation layer 21 may be sequentially formed thereon. In this case, damages to the thin-film insulation layer 21 during the fabrication process may be prevented (or reduced).

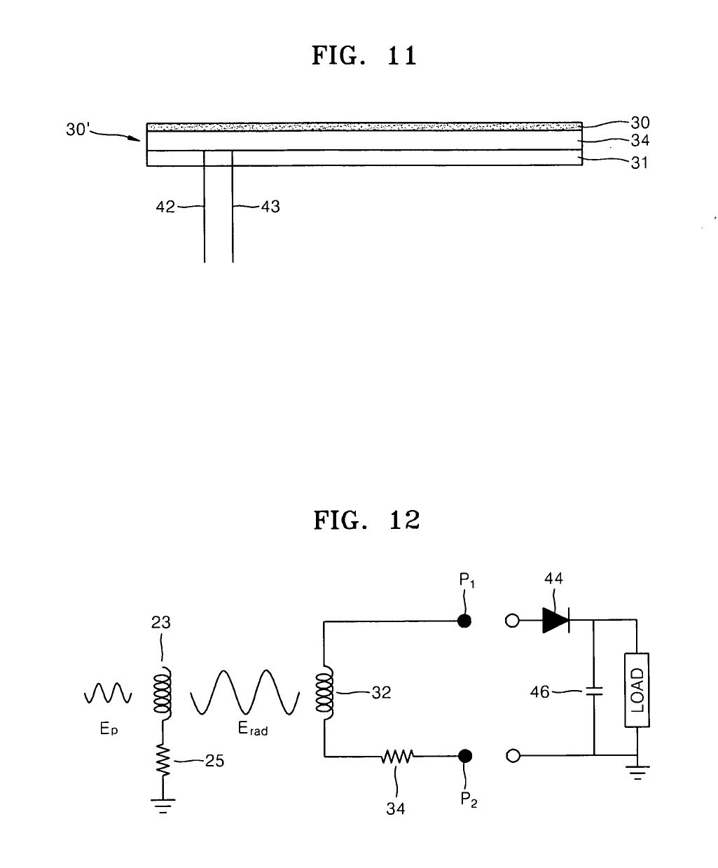

FIG. 11 is a schematic diagram showing the structure of a secondary nano-helix layer according to example embodiments.

The second nano-helixes 32 in the secondary nano-helix layer 30 may also be damaged by a high voltage or high current. An additional insulation layer may be interposed between the second nano-helixes 32 and the insulation layer 31 to prevent (or reduce the likelihood of) the second nano-helixes 32 from being damaged. For example, in FIG. 11, a secondary nano-helix layer 30′ includes an additional insulation layer 34 interposed between the second nano-helixes 32 and the insulation layer 31. The additional insulation layer 34 may be formed of the same electromagnetic wave transmissive material as the insulation layer 31. The wires 42 and 43 of the diode unit layer 40 extend only through the insulation layer 31. The second nano-helixes 32 and the wires 42 and 43 do not directly contact each other. As such, most of the voltage is drop in the additional insulation layer 34, and thus the second nano-helixes 32 may be protected.

FIG. 12 is a schematic diagram of an equivalent circuit of an energy harvesting device according to example embodiments including insulation layers for providing current resistance.

Compared to the equivalent circuit shown in FIG. 3, the equivalent circuit shown in FIG. 12 further includes a resistance 25 between a primary coil and a ground and a resistance 34 between a secondary coil and a load.

Descriptions given hitherto refer to a case in which nano-helixes are horizontally laid and grown on a substrate. However, nano-helixes may be vertically grown on a substrate.

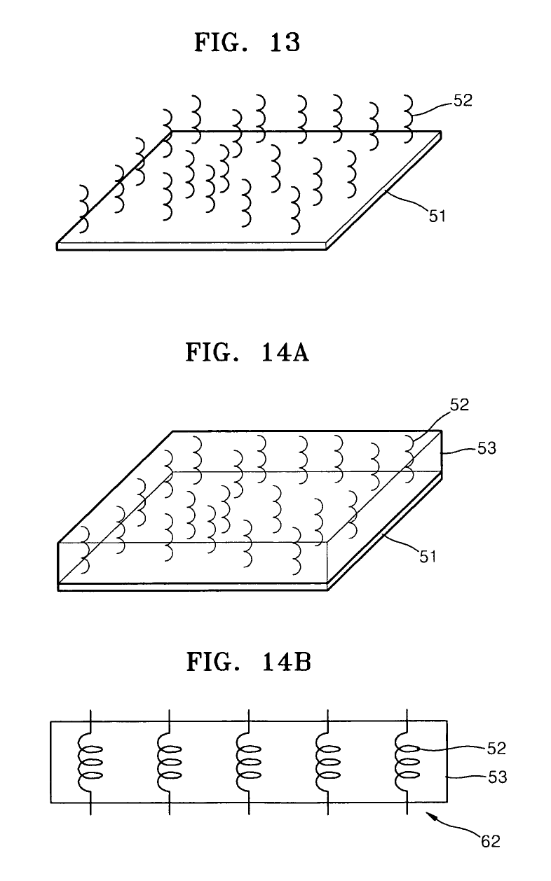

FIG. 13 shows a plurality of nano-helixes vertically grown on a growth substrate.

Referring to FIG. 13, electric connections to both ends of a vertically-grown nano-helix 52 may be easier to form.

FIGS. 14A and 14B are schematic diagrams showing the structure of nano-helix layers according to example embodiments.

As shown in FIG. 14A, an insulation layer 53 is formed on the growth substrate 51, on which the nano-helixes 52 are vertically grown. The vertical nano-helixes 52 are covered by the insulation layer 53 and are fixed. The insulation layer 53 may be formed of a dielectric material that transmits incident electromagnetic waves. For example, when the incident electromagnetic waves are visible rays, the insulation layer 53 may be formed of a material transparent with respect to visible rays. The growth substrate 51 may subsequently be removed, and the upper and lower surfaces of the insulation layer 53 are etched until the both ends of the nano-helixes 52 are exposed. As a result, a nano-helix layer 62 as shown in FIG. 14B may be obtained.

Referring to FIG. 14B, the plurality of vertical nano-helixes 52 are arranged within the insulation layer 53, and the both ends of each of the nano-helixes 52 are exposed outside the upper and lower surfaces of the insulation layer 53. Therefore, electric connection to both ends of the nano-helixes 52 may be easily formed.

FIG. 15 is a schematic diagram of an energy harvesting device including the nano-helix layer shown in FIG. 14B.

Referring to FIG. 15, an electrode 61 may be disposed below the nano-helix layer 62. If the incident electromagnetic waves are visible rays, the electrode 61 may be formed of a transparent conductive material (e.g., ITO). Because both ends of the nano-helixes 52 are exposed to outside as described above, the lower ends of the nano-helixes 52 may be electrically connected to the electrode 61. A p-type semiconductor layer 63a, a n-type semiconductor layer 63b, a first conductor layer 64a, a dielectric layer 64b and a second conductor layer 64c may be successively stacked on the nano-helix layer 62. The upper ends of the nano-helixes 62 may be electrically connected to the p-type semiconductor layer 63a. The p-type semiconductor layer 63a and the n-type semiconductor layer 63b form a diode layer 63 for rectification.

The first conductor layer 64a, the dielectric layer 64b and the second conductor layer 64c form a condenser layer 64 for equalizing rectified currents. The electrode 61 and the second conductor layer 64c are connected to ground, and the n-type semiconductor layer 63b is connected to an output. Although FIG. 15 shows that the p-type semiconductor layer 63a is stacked first, and then the n-type semiconductor layer 63b is stacked thereafter, the positions of the semiconductor layers 63a and 63b may be reversed. For example, the n-type semiconductor layer 63b may be stacked first and connected to the nano-helixes 52, and then the p-type semiconductor layer 63a may be stacked thereon and connected to an output.

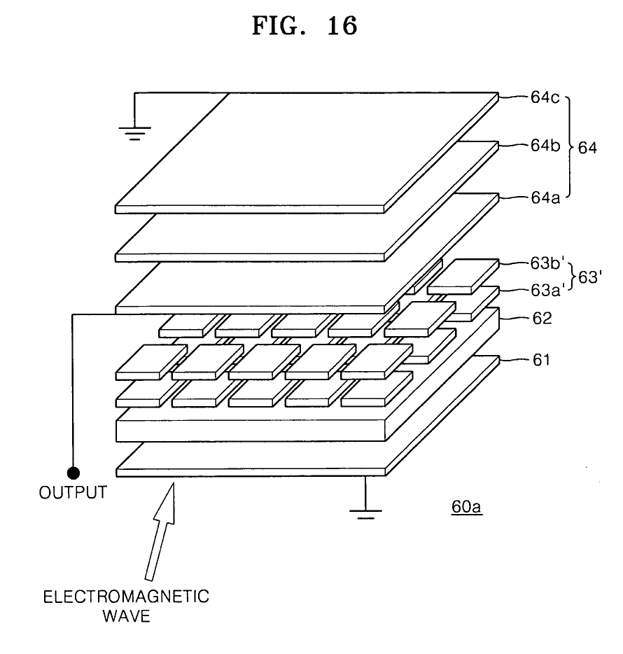

FIG. 16 is a schematic diagram of another energy harvesting device including the nano-helix layer shown in FIG. 14B.

Compared to the energy harvesting device 60 shown in FIG. 15, the energy harvesting device 60a shown in FIG. 16 includes a diode layer 63′, which is divided into a plurality of cells. All other configurations of the energy harvesting device 60a except the diode layer 63′ are identical to those of the energy harvesting device 60 shown in FIG. 15. Light or electromagnetic waves incident onto the nano-helix layer 62 via the electrode 61 may not have the same phase throughout the entire energy harvesting device 60a. Therefore, each of the currents induced by each of the nano-helixes 52 may flow in different directions. As a result, currents induced in different directions may compensate for each others, and thus the overall efficiency of the energy harvesting device 60a may decrease.

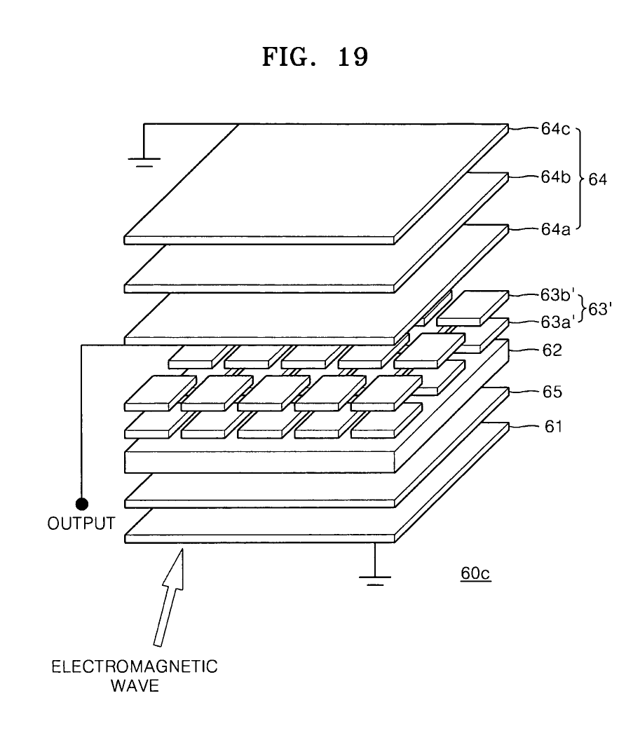

In the energy harvesting device 60a shown in FIG. 16, the diode layer 63′ is divided into a plurality of cells to minimize compensation between currents induced in different directions. A p-type semiconductor layer 63a′ and an n-type semiconductor layer 63b′ are also divided into a plurality of cells. One of the plurality of cells of the diode layer 63′ may be connected in a one-to-one relationship to one of the nano-helixes 52 in the nano-helix layer 62. In this case, loss due to compensation between induced currents may not occur at all, as shown in an equivalent circuit shown in FIG. 18. However, one of the plurality of cells of the diode layer 63′ may be connected to a plurality of nano-helixes 52 in the nano-helix layer 62.

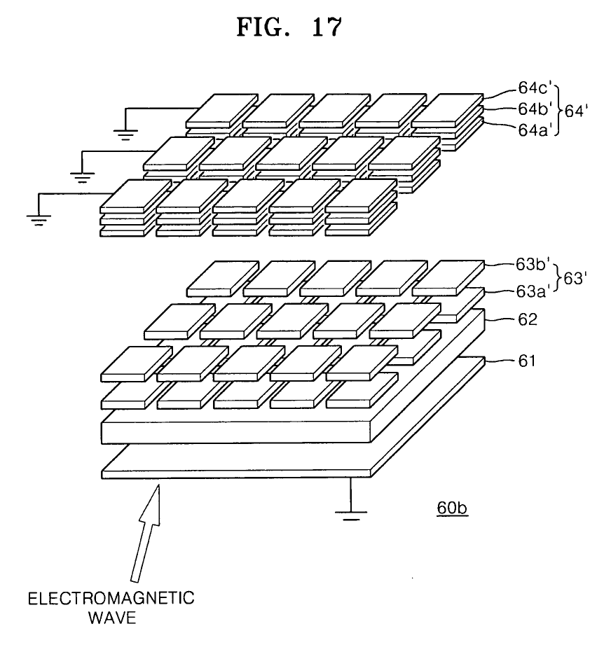

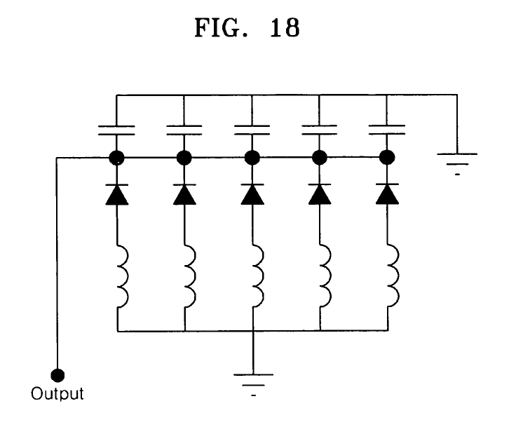

FIG. 17 is a schematic diagram of an energy harvesting device according to example embodiments.

Compared to the energy harvesting device 60a shown in FIG. 16, the energy harvesting device 60b shown in FIG. 17 includes a condenser layer 64′ divided into a plurality of cells. Each of the plurality of cells of the condenser layer 64′ includes a first conductor layer 64a′, a dielectric layer 64b′ and a second conductor material layer 64c′. All other components of the energy harvesting device 60b except the condenser layer 64′ are identical to those of the energy harvesting device 60a shown in FIG. 16.

FIG. 18 shows an equivalent circuit of the energy harvesting device shown in FIG. 17.

FIG. 19 is a schematic diagram of an energy harvesting device including the nano-helix layer shown in FIG. 14B.

Compared to the energy harvesting device 60a shown in FIG. 16, the energy harvesting device 60c shown in FIG. 19 includes a resistance layer 65 between the nano-helix layer 62 and the electrode 61. All other components of the energy harvesting device 60c shown in FIG. 19 except the resistance layer 65 are identical to those of the energy harvesting device 60a shown in FIG. 16.

In FIG. 19, the nano-helixes 52 in the nano-helix layer 62 are connected to the resistance layer 65. Thus, voltage drops occur in the resistance layer 65, and thus application of a substantially large current or large voltage application to the nano-helixes 52 in the nano-helix layer 62 may be prevented (or reduced). Damages to the nano-helixes 52 due to overcurrent or overvoltage may be prevented (reduced), and thus the life span of the energy harvesting device 60c may increase. The resistance layer 65 may be formed of an insulation material that transmits incident electromagnetic waves.

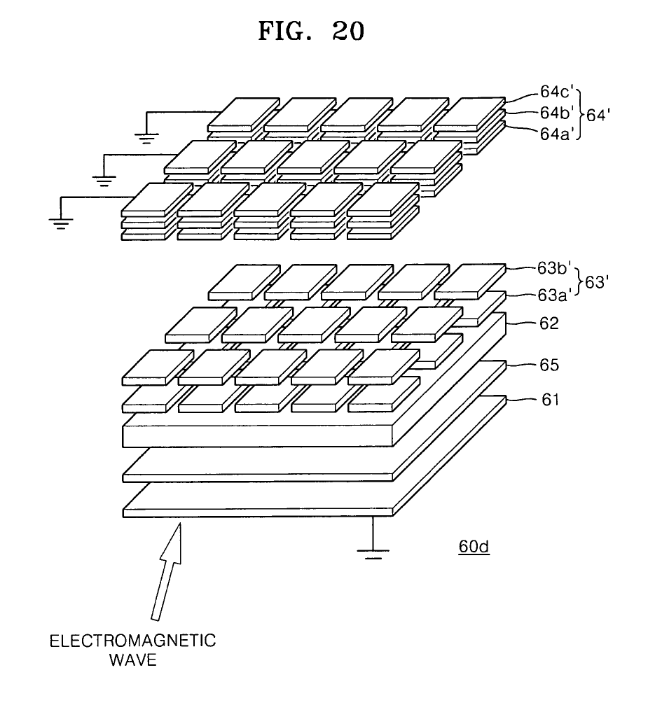

FIG. 20 is a schematic diagram of an energy harvesting device according to example embodiments.

Compared to the energy harvesting device 60c shown in FIG. 19, the energy harvesting device 60d shown in FIG. 20 includes a condenser layer 64′ divided into a plurality of cells. Like in the embodiment shown in FIG. 17, each of the plurality of cells of the condenser layer 64′ includes the first conductor layer 64a′, the dielectric layer 64b′ and the second conductor material layer 64c′. All other components of the energy harvesting device 60d except the condenser layer 64′ are identical to those of the energy harvesting device 60c shown in FIG. 19.

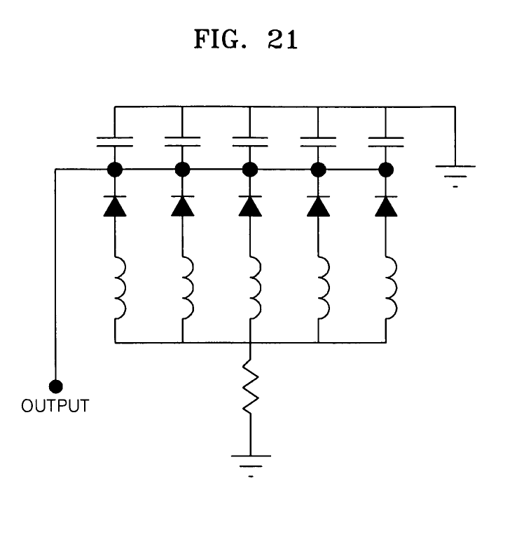

FIG. 21 shows an equivalent circuit of the energy harvesting device shown in FIG. 20.

Referring to FIG. 21, a resistance is connected between a nano-helix and ground.

In case of growing nano-helixes on transparent electrodes, which may be formed of ITO, the nano-helixes may be grown and the lower ends of the nano-helixes are connected to the electrodes. Therefore, electrical connections to both ends of the nano-helixes may be formed easier.

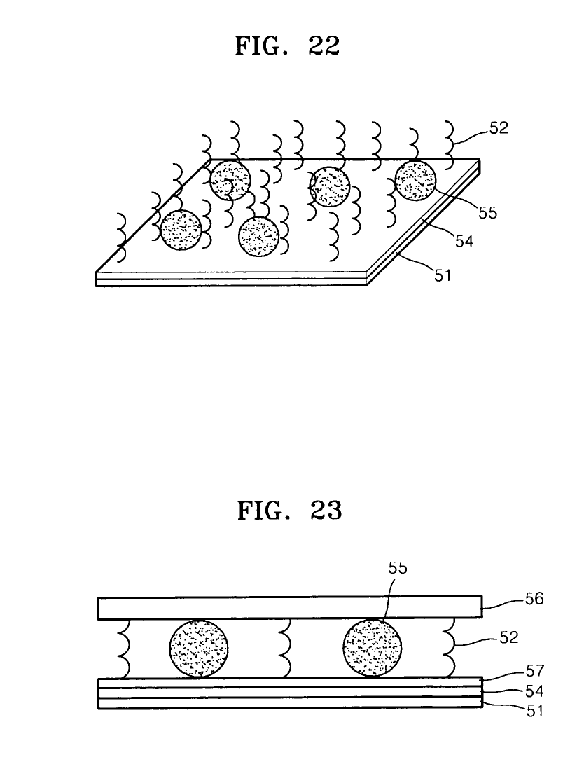

Referring to FIG. 22, an electrode layer 54 is formed on the growth substrate 51, and the nano-helixes 52 are vertically grown. As shown in FIG. 14A, an energy harvesting device as shown in FIG. 15, 16, 17, 19 or 20 may be fabricated by disposing the insulation layer 53 to cover the electrode layer 54 and etching the upper surface of the insulation layer 53 until the upper ends of the nano-helixes 52 are exposed. The growth substrate 51 may be formed of an insulation material that transmits incident electromagnetic waves, and also the electrode layer 54 may be formed of a conductive material that transmits incident electromagnetic waves.

Alternatively, as shown in FIG. 22, a plurality of dielectric spacers 55 may be arranged on the electrode layer 54. For example, the dielectric spacers 55 may be nano-spheroids formed of SiO₂.

FIG. 23 is a schematic diagram showing the structure of nano-helix layers according to example embodiments.

Referring to FIG. 23, a diode layer 56 may be disposed on the dielectric spacers 55. The dielectric spacers 55 are formed having a diameter smaller than the length of the nano-helixes 52. The upper ends of the nano-helixes 52 may be electrically connected to the diode layer 56. Because the nano-helixes 52 have elasticity like springs, the nano-helixes 52 may not be damaged even if the nano-helixes 52 are slightly pressed by the diode layer 56. The dielectric spacers 55 support the diode layer 56. FIG. 23 shows an additional resistance layer 57 disposed on the electrode layer 54. The resistance layer 57 may be formed of an insulation material that transmits incident light. The resistance layer 57 may be omitted in the example embodiments shown in FIG. 23. In the case of using the resistance layer 57, the nano-helixes 52 may be grown on the resistance layer 57 instead of the electrode layer 54. Although not shown in FIG. 23, a condenser layer for equalizing rectified currents may be disposed on the diode layer 56.

The method of growing nano-helixes vertically as shown in FIG. 13 may also be applied to the embodiment shown in FIG. 1. The first nano-helixes 23 in the primary nano-helix layer 20 and the second nano-helixes 32 of the secondary nano-helix layer 30, which are shown in FIG. 1, may also be vertically grown. Although the primary nano-helix layer 20 and the secondary nano-helix layer 30 are separately disposed in FIG. 1, one of the nano-helixes in the secondary nano-helix layer 30 may function as a primary coil, and other nano-helixes surrounding the nano-helix may function as secondary coils. The energy harvesting device 10 may be formed of the secondary nano-helix layer 30 without the primary nano-helix layer 20.

Energy harvesting devices according to example embodiments may be used as a power source in various devices including mobile devices (e.g., cellular phones, PDAs and similar devices), imaging devices (e.g., cameras), light sources (e.g., lamps) and vehicles (e.g., cars, trains, airplanes and other forms of transportation).

The foregoing is illustrative of example embodiments and is not to be construed as limiting thereof. Although a few example embodiments have been described, those skilled in the art will readily appreciate that many modifications are possible in example embodiments without materially departing from the novel teachings and advantages. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

What is claimed is:

1. An energy harvesting device, comprising:
a plurality of first nano-helixes amplifying incident electromagnetic waves;
a plurality of second nano-helixes inducing currents from the electromagnetic waves amplified by the first nano-helixes; and
a diode rectifying induced currents generated by the second nano-helixes.

2. The energy harvesting device of claim 1, wherein the incident electromagnetic waves are generated by a natural light source, an artificial light source, a wireless station or a wireless device.

3. The energy harvesting device of claim 1, wherein the first and second nano-helixes are formed of a conductive material.

4. The energy harvesting device of claim 1, wherein the first and second nano-helixes are close to each other.

5. The energy harvesting device of claim 1, wherein the first nano-helixes are on a first substrate, and the second nano-helixes are on a second substrate.

6. The energy harvesting device of claim 5, wherein the first substrate is stacked on the second substrate.

7. The energy harvesting device of claim 5, further comprising a plurality of the first substrates, wherein the first substrates are stacked on each other.

8. The energy harvesting device of claim 5, wherein the first nano-helixes and the second nano-helixes are horizontally or vertically grown on the first substrate and the second substrate, respectively.

9. The energy harvesting device of claim 1, further comprising an equalizing circuit connected to the diode, wherein the equalizing circuit is configured to equalize the rectified currents.

10. The energy harvesting device of claim 9, further comprising a storage battery connected to the equalizing circuit, wherein the storage battery is configured to store the equalized currents.

11. The energy harvesting device according to claim 1, further comprising:
a primary nano-helix layer having the first nano-helixes;
a secondary nano-helix layer having the second nano-helixes; and
a diode unit layer having a plurality of the diodes.

12. The energy harvesting device of claim 11, wherein the primary nano-helix layer includes:
a first insulation layer; and
a ground electrode on the first insulation layer, wherein the first nano-helixes are on the first insulation layer and the ground electrode and are electrically connected to the ground electrode at a point.

13. The energy harvesting device of claim 12, wherein the plurality of first nano-helixes are randomly distributed on the first insulation layer.

14. The energy harvesting device of claim 13, wherein the plurality of first nano-helixes are covered and fixed by a coating layer on the first insulation layer.

15. The energy harvesting device of claim 12, wherein a thickness of the first insulation layer is from about 1-nm to about 100-μm.

16. The energy harvesting device of claim 12, wherein the ground electrode includes a plurality of conductive wires on the first insulation layer, the conductive wires being in a side-by-side configuration.

17. The energy harvesting device of claim 12, further comprising a second insulation layer between the ground electrode and the first nano-helixes.

18. The energy harvesting device of claim 17, wherein the primary nano-helix layer includes the first nano-helixes, the second insulation layer, the ground electrode and the first insulation layer sequentially arranged on a substrate.

19. The energy harvesting device of claim 11, further comprising at least two of the primary nano-helix layers successively stacked in a travelling direction of the incident electromagnetic waves, wherein the at least two primary nano-helix layers have the same structure.

20. The energy harvesting device of claim 11, the secondary nano-helix layer includes a third insulation layer having the second nano-helixes thereon.

21. The energy harvesting device of claim 20, wherein the diode unit layer includes a plurality of diode cells, each of the diode cells having a pair of wires that penetrate the third insulation layer and that are electrically connected to both ends of the second nano-helixes, and one of the diodes for rectifying induced currents flowing in the pair of wires.

22. The energy harvesting device of claim 21, further comprising a plurality of condensers connected to each of the diode cells, wherein the condensers are configured to equalize the rectified currents.

23. The energy harvesting device of claim 21, wherein the diode cells are connected to each other in series, in parallel or in a combination of a serial connection and a parallel connection.

24. The energy harvesting device of claim 21, further comprising a fourth insulation layer between the third insulation layer and the second nano-helixes.

25. The energy harvesting device of claim 20, wherein the plurality of second nano-helixes are covered and fixed by a coating layer on the third insulation layer.

26. An energy harvesting device comprising:
a nano-helix layer having a plurality of vertically-arranged nano-helixes;
an electrode connected to a first end of each of the nano-helixes; and
a diode layer connected to a second end of each of the nano-helixes.

27. The energy harvesting device of claim 26, wherein the nano-helix layer includes an insulation layer, the plurality of nano-helixes being arranged in the insulation layer such that the first end of each of the nano-helixes protrudes from a lower surface of the insulation layer and the second end of each of the nano-helixes protrudes from an upper surface of the insulation layer.

28. The energy harvesting device of claim 26, wherein the diode layer includes:
a first semiconductor layer on an upper surface of the nano-helix layer; and
a second semiconductor layer on the first semiconductor layer, wherein the second semiconductor layer includes an opposite-type dopant than that of the first semiconductor layer.

29. The energy harvesting device of claim 28, wherein the plurality of nano-helixes are electrically connected to the first semiconductor layer.

30. The energy harvesting device of claim 28, further comprising a condenser layer on an upper surface of the diode layer.

31. The energy harvesting device of claim 30, wherein the condenser layer includes:
a first conductor layer on the second semiconductor layer;
a dielectric layer on the first conductor layer; and
a second conductor layer on the dielectric layer.

32. The energy harvesting device of claim 31, wherein the electrode and the second conductor layer are connected to a ground, and the second semiconductor layer is connected to an output.

33. The energy harvesting device of claim 26, wherein the diode layer is divided into a plurality of diode cells.

34. The energy harvesting device of claim 33, wherein one of the diode cells of the diode layer is connected to one of the nano-helixes of the nano-helix layer.

35. The energy harvesting device of claim 26, further comprising a resistance layer between the nano-helix layer and the electrode.

36. The energy harvesting device of claim 26, wherein the nano-helix layer includes a substrate and the electrode layer, the electrode layer being on the substrate and the plurality of nano-helixes being vertically grown on the electrode layer, and
the diode layer is on the nano-helix layer and electrically connected to the plurality of nano-helixes.

37. The energy harvesting device of claim 36, further comprising a plurality of dielectric spacers between the electrode layer of the nano-helix layer and the diode layer, wherein the dielectric spacers support the diode layer.

38. The energy harvesting device of claim 36, further comprising an insulation layer between the electrode layer of the nano-helix layer and the diode layer.

39. The energy harvesting device of claim 36, further comprising a resistance layer between the electrode layer and the nano-helixes.

40. The energy harvesting device of claim 36, further comprising a condenser layer on an upper surface of the diode layer.
